(19) United States
(12) Patent Application Publication
(10) Pub. No.: US 2020/0126824 A1
(43) Pub. Date: Apr. 23, 2020

(54) SUPER THIN HEATING DISK

(71) Applicants: Kuo Yang Ma, Taipei City (TW); Mu-Chun Ho, Taipei City (TW); Wei-Chuan Chou, Taipei City (TW); Pei-Shan Li, Taipei City (TW); Yi Hsiang Chen, Taipei City (TW); Cheng Feng Li, Taipei City (TW)

(72) Inventors: Kuo Yang Ma, Taipei City (TW); Mu-Chun Ho, Taipei City (TW); Wei-Chuan Chou, Taipei City (TW); Pei-Shan Li, Taipei City (TW); Yi Hsiang Chen, Taipei City (TW); Cheng Feng Li, Taipei City (TW)

(21) Appl. No.: 16/162,415

(22) Filed: Oct. 17, 2018

(51) Int. Cl. H01L 21/67; H05B 3/12

(52) U.S. Cl. CPC H01L 21/67103; H05B 3/12

(57) ABSTRACT

A super thin heating disk includes an upper cover made of metal, the upper cover being formed with a receiving groove; a lower cover made of metal and installed within the receiving groove; the heating coil being distributed in the receiving groove; a heating coil installed within the receiving groove, two ends of the heating coil being installed with two electrodes, respectively, which are connected to external positive and negative electrodes for current conduction; a thermal couple installed in the receiving groove for detecting temperatures of the heating coil; the thermal couple being connected to two connection wires for conducting external transmission lines so that detection temperature data can be transferred out; and two insulation layers installed in the receiving groove and at an upper and a lower side of the heating coil.

### FIELD OF THE INVENTION

The present invention is related to semiconductor manufacturing, and in particular to a super thin heating disk.

### BACKGROUND OF THE INVENTION

In semiconductor flip chip process, during wafer packaging and fan out packaging, before sputtering metals, the electrodes will have gasification material. Therefore, argon plasma bombarding is used to remove oxides. This process must be down in a very high vacuum, however, in this process, polyimide is used as a protecting layer which encloses the wafer. However, in solidification, vapor within the polyimide will be released in high vacuum environment. This will induce a cleaned wafer to be oxidized again, therefore, before plasma cleaning, the wafer with the polyimide must perform the process of reduction of vapor.

There are some ways for reduction of vapor including the following ways:

Bulb heating, the wafer is heating within a casing with a plurality of bulbs therein. This way has the advantages of quick, high efficiency and low cost, but it is non-uniform heating and uneasy to control so that the temperature difference can not be controlled with 5 degree C. It is very difficult to heating a plurality of wafers in one cavity. The heating of different wafer will interfere heating of another wafer.

Furnace heating, in that the wafers are placed within a furnace with a plurality of heaters installed therein. The heating is by radiation, heating speed is low and is non-uniform. Under consideration of a wafer which is heated slower, the baking time is prolonged. As a result, the whole efficiency become low.

Heating plate, each time only one wafer is heated. It has the advantage of well control but the efficiency is very low and thus it can not match the requirement of fan not packaging which need long heating time. Furthermore the prior heating disk is thicker and heavier, and thus it is not suitable to place a plurality of wafer in a narrow space. Therefore, a vapor removing reactor is added to a vacuum transfer chamber, but the reactor occupies a space and a processing reactor must be removed, and thus reduce the production of wafers.

### SUMMARY OF THE INVENTION

Accordingly, the object of the present invention is to provide a super thin heating disk, wherein in the super thin heating disk of the present invention, by above mentioned special structure, it is thinner than prior arts, and has a preferred heating stability and heat uniformly distribution. Therefore, more heating disks can be placed into a narrow wafer carrier reactor chamber so that a plurality of wafers can be heated at the same time and therefore the production rate is greatly increased. The super thin heating disk of the present invention can be used in semiconductor manufacturing process, moreover, the present invention is also suitable for other fields which need supper thin heating disks due to the confinement of space.

To achieve above object, the present invention provides a super thin heating disk, comprising: an upper cover made of metal, the upper cover being formed with a receiving groove; a lower cover made of metal and installed within the receiving groove; the heating coil being distributed in the receiving groove; a heating coil installed within the receiving groove, two ends of the heating coil being installed with two electrodes, respectively, which are connected to external positive and negative electrodes for current conduction; a thermal couple installed in the receiving groove for detecting temperatures of the heating coil; the thermal couple being connected to two connection wires for conducting external transmission lines so that detection temperature data can be transferred out; and two insulation layers installed in the receiving groove and at an upper and a lower side of the heating coil.

The present invention further includes a plurality of combining studs, a peripheral edge of a bottom of the upper cover is formed with a protrusion; an inner side of the protrusion is formed with a stepped edge; an inner side of the stepped edge is formed with a receiving groove; a plurality of supporting blocks are installed in the receiving groove and have the same height as that of the protrusion; the stepped edge and the plurality of supporting blocks are formed with a plurality of screw holes; the lower cover engages in the space enclosed by the protrusion and the top of the lower cover resists against the stepped edge and the plurality of supporting blocks and the bottom of the lower cover is at the same height with the upper edge of the protrusion; the lower cover is formed with a plurality of through holes corresponding to the screw holes; the plurality of combining studs passes through the through holes of the lower cover and then screw into the screw holes of the upper cover to combine the upper cover to the lower cover.

### BRIEF DESCRIPTION OF THE DRAWINGS

FIG. 1 is an exploded schematic view of the present invention.

FIG. 2 is an enlarged schematic view of the present invention.

FIG. 3 is an elevational view of the present invention.

FIG. 4 is a perspective view of the present invention.

FIG. 5 is an enlarged schematic cross sectional view along line A-A in FIG. 4.

FIG. 6 is a schematic view showing heating coil on the upper cover according to the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

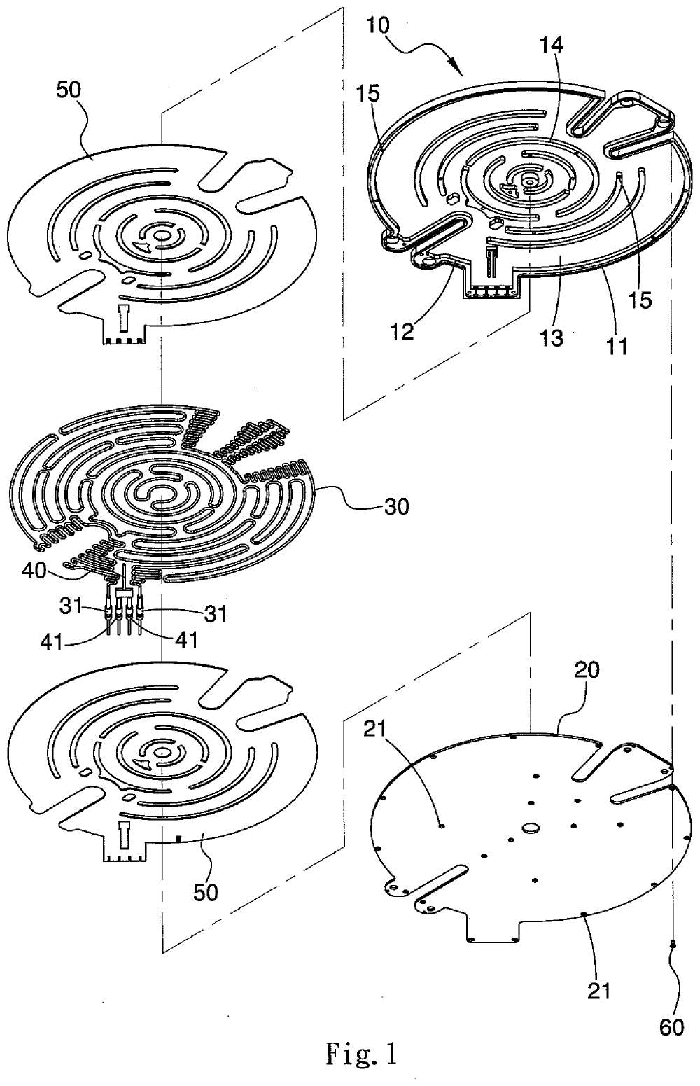

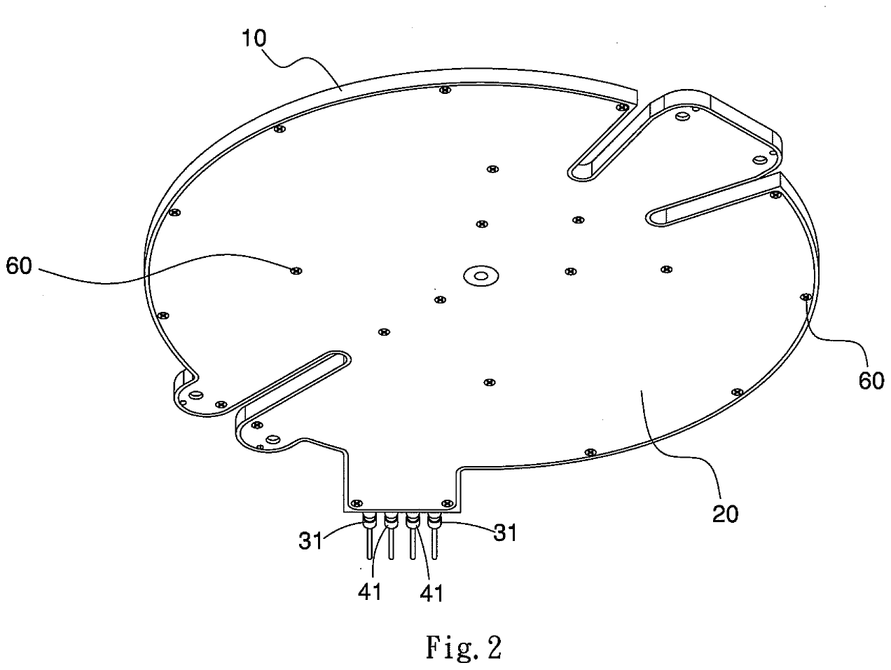

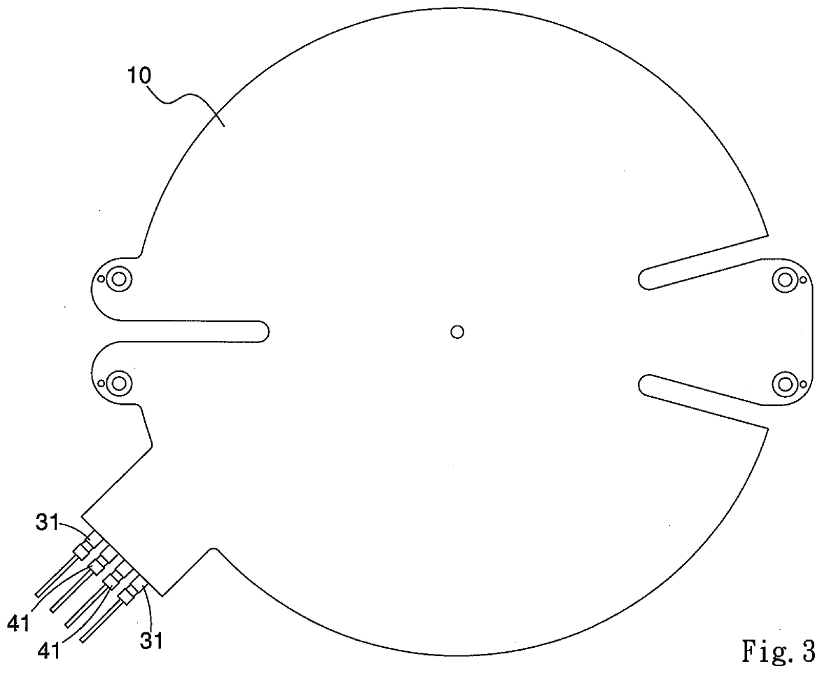

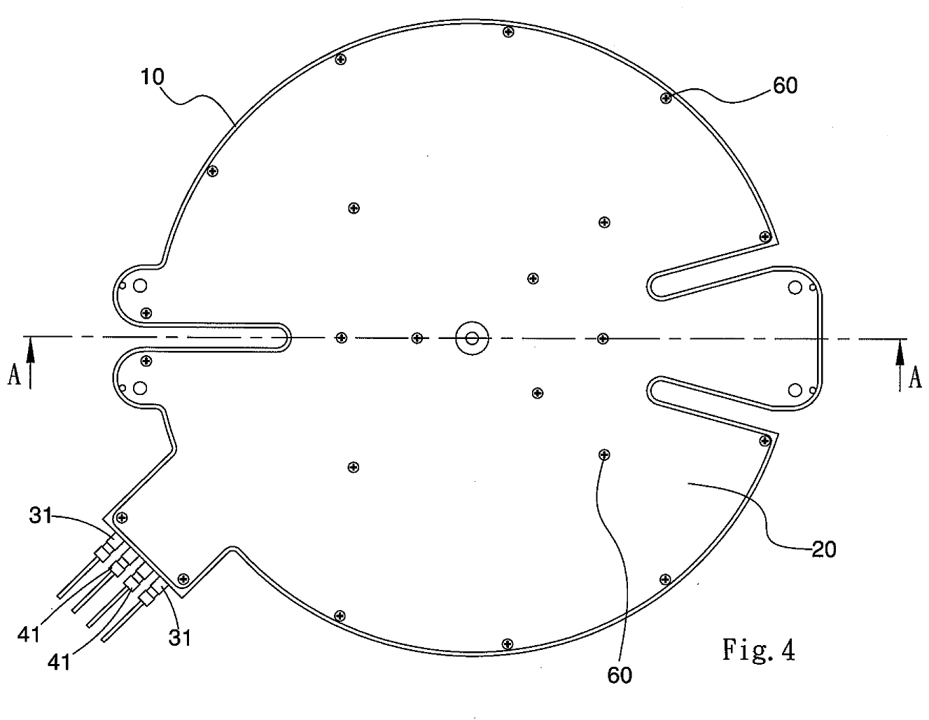

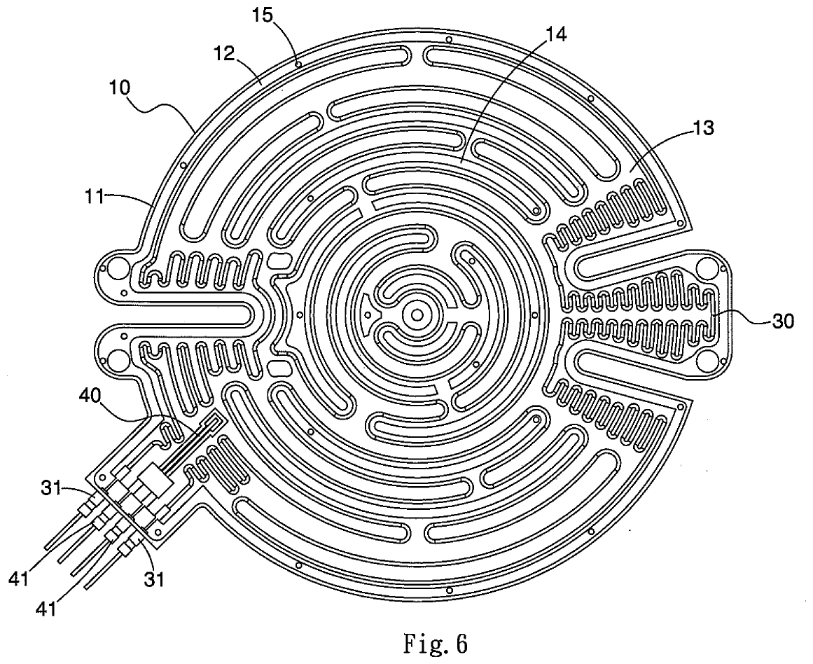

Referring to FIGS. 1 to 6, the structure of the present invention is illustrated. The present invention includes the following elements.

An upper cover 10 is made of metal, such as aluminum alloy, or stainless steel). A peripheral edge of a bottom of the upper cover 10 is formed with a protrusion 11. An inner side of the protrusion 11 is formed with a stepped edge 12. An inner side of the stepped edge 12 is formed with a receiving groove 13. A plurality of supporting blocks 14 are installed in the receiving groove 13 and have the same height as that of the protrusion 11. The stepped edge 12 and the plurality of supporting blocks 14 are formed with a plurality of screw holes 15.

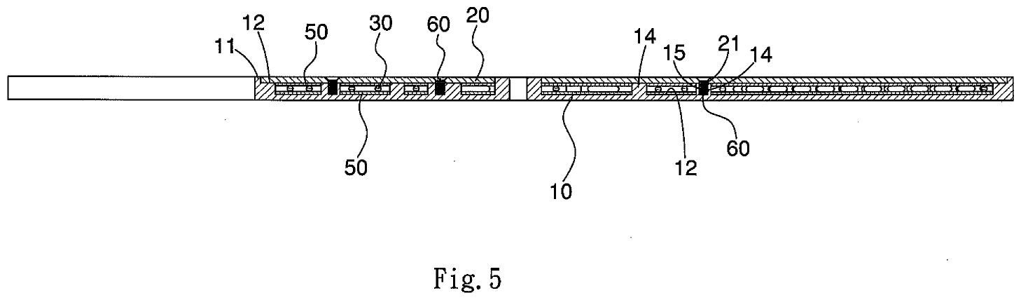

A lower cover 20 is made of metal (such as aluminum alloy or stainless steel). The lower cover 20 can engage in the space enclosed by the protrusion 11 and the top of the lower cover 20 is resists against the stepped edge 12 and the plurality of supporting blocks 14 and the bottom of the lower cover 20 is flushed (at the same height) with the upper edge of the protrusion 11 as illustrated in FIG. 5. The lower cover 20 is formed with a plurality of through holes 15 corresponding to the screw holes 21.

A heating coil 30 is made of nickel and is installed within the receiving groove 13. The heating coil 30 is distributed in the receiving groove 13. The heating coil 30 may be heated to a temperature of 750 degree C. For a lower temperature areas of the receiving groove 13, the heating coil 30 is high-densely distributed and in higher temperature areas, the heating coil 30 is low-densely distributed so that the temperature is uniformed distributed in the receiving groove 13. Two ends of the heating coil 30 are installed with two electrodes 31, respectively, which are connected to external positive and negative electrodes for current conduction.

A thermal couple 40 is installed in the receiving groove 13 for detecting the temperature of the heating coil 30. The thermal couple 40 is connected to two connection wires 41 for conducting external transmission lines so that detection temperature data can be transferred out.

Two insulation layers 50 are installed in the receiving groove 13 and are at an upper and a lower side of the heating coil 30. The two insulation layers 50 have through holes to expose the plurality of supporting blocks 14. The two insulation layers 50 are made of meca.

A plurality of combining studs 60 passes through the through holes 21 of the lower cover 20 and then screw into the screw holes 15 of the upper cover 10 to combine the upper cover 10 to the lower cover 20. One end of each through hole 21 has an embedding groove to receive a head of a respective stud 60. FIG. 1 only shows only stud 60, while practically, there are a plurality of studs 60.

In the present invention, when the super thin heating disk is used in a heating temperature below 400 degree C., materials of the upper cover 10 and lower cover 20 are aluminum alloy. When the super thin heating disk is used in a heating temperature below 400 degree C., materials of the upper cover 10 and lower cover 20 are stainless steel.

In the super thin heating disk of the present invention, by above mentioned special structure, it is thinner than prior arts, and has a preferred heating stability and heat uniformly distribution. Therefore, more heating disks can be placed into a narrow wafer carrier reactor chamber so that a plurality of wafers can be heated at the same time and therefore the production rate is greatly increased.

The super thin heating disk of the present invention can be used in semiconductor manufacturing process, moreover, the present invention is also suitable for other fields which need supper thin heating disks due to the confinement of space.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A super thin heating disk, comprising:
an upper cover made of metal, the upper cover being formed with a receiving groove;
a lower cover made of metal and installed within the receiving groove; the heating coil being distributed in the receiving groove;
a heating coil installed within the receiving groove, two ends of the heating coil being installed with two electrodes, respectively, which are connected to external positive and negative electrodes for current conduction;
a thermal couple installed in the receiving groove for detecting temperatures of the heating coil; the thermal couple being connected to two connection wires for conducting external transmission lines so that detection temperature data can be transferred out; and
two insulation layers installed in the receiving groove and at an upper and a lower side of the heating coil.

2. The super thin heating disk as claimed in claim 1, further including a plurality of combining studs, a peripheral edge of a bottom of the upper cover is formed with a protrusion; an inner side of the protrusion is formed with a stepped edge; an inner side of the stepped edge is formed with a receiving groove; a plurality of supporting blocks are installed in the receiving groove and have the same height as that of the protrusion; the stepped edge and the plurality of supporting blocks are formed with a plurality of screw holes; the lower cover engages in the space enclosed by the protrusion and the top of the lower cover resists against the stepped edge and the plurality of supporting blocks and the bottom of the lower cover is at the same height with the upper edge of the protrusion; the lower cover is formed with a plurality of through holes corresponding to the screw holes; the plurality of combining studs passes through the through holes of the lower cover and then screw into the screw holes of the upper cover to combine the upper cover to the lower cover.

3. The super thin heating disk as claimed in claim 2, wherein material of the upper cover and lower cover is aluminum alloy.

4. The super thin heating disk as claimed in claim 2, wherein the upper cover and lower cover are made of stainless steels.

5. The super thin heating disk as claimed in claim 3, wherein material of the heating coil is nickel.

6. The super thin heating disk as claimed in claim 2, wherein material of the insulation layers are mica.

7. The super thin heating disk as claimed in claim 2, wherein the two insulation layers exposes out of the supporting blocks,

8. The super thin heating disk as claimed in claim 3, wherein the heating coil is heated to 750 degree C.

9. The super thin heating disk as claimed in claim 2, wherein for a lower temperature areas of the receiving groove, the heating coil is high-densely distributed and in higher temperature areas, the heating coil is low-densely distributed so that the temperature is uniformed distributed in the receiving groove.

10. The super thin heating disk as claimed in claim 2, wherein one end of each through hole has an embedding groove to receive a head of a respective stud.
